(19) United States
(12) Patent Application Publication
(10) Pub. No.: US 2005/0085007 A1
(43) Pub. Date: Apr. 21, 2005

(54) Joining material stencil and method of use

(76) Inventors: Chuong Vu, Roseville, CA (US); Lidia Warnes, Wilton, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/690,177

(22) Filed: Oct. 20, 2003

(51) Int. Cl. H01L 21/44

(52) U.S. Cl. 438/106

(57) ABSTRACT

A stencil for the deposition of a heat yieldable joining material includes at least one pattern formation member and at least one channel formation portion associated with the pattern formation member.

### BACKGROUND

Production circuit boards typically start out as thin sheets of fiberglass (about 1 mm thick) that are completely covered on both sides with very thin sheets of metal (typically copper). A “standard” circuit board might use a one ounce copper process, which means that one ounce of copper is evenly spread across one square foot of circuit board. During the manufacturing process, wire patterns are “printed” onto the copper surfaces using a compound that resists etching (hence the name Printed Circuit Board or PCB). Once printed, the boards are subjected to a chemical etching process that removes all exposed copper. The remaining un-etched copper forms traces that will interconnect the circuit board components and small pads that define the regions where component leads will be attached.

In a PCB that uses through-hole technology, holes are drilled through the pads so that component leads can be inserted and then fastened (soldered) in place. In a PCB that uses surface-mount technology, component leads are soldered directly to the pads on the surface of the PCB. The soldered contact area needs to be as large as possible in order to form a good physical and electrical connection between the PCB and the component.

On all but the simplest PCBs, traces must be printed on more than one surface of fiberglass to allow for all the required component interconnections. Each surface containing printed wires is called a layer. In a relatively simple PCB that requires only two layers, a single piece of fiberglass may be used since wires can be printed on both sides. In a more complex PCB requiring several layers, individual circuit boards are manufactured separately and then laminated together to form one multi-layer circuit board. PCB designs vary in complexity from simple two-layer circuit boards to circuit boards having more than 20 layers. To connect wire traces of two or more layers, small holes called vias are drilled through the wire traces and fiberglass board at the point where the wire traces on the different layers cross. The interior surface of these holes is then coated with metal so that electric current can flow through the vias connecting wire traces between layers.

Complexities arise in joining a PCB with electronic components when the vias become clogged with solder attributable to capillary action of the vias drawing in melted solder. Solder mask are commonly used to cover the vias, which are in turn coated with solder paste in order to maximize contact area between the electronic component and the PCB. During heating, air trapped within the vias expands and escapes, forcing its way through the solder mask and the overlying layer of melted solder. The escaping gas carries melted solder with it, which may splash on the PCB, resulting in shorts. A shorted PCB is defective and must be rejected thereby increasing the per-unit cost of non-defective PCBs.

### SUMMARY

A stencil for deposition of a heat yieldable joining material includes at least one pattern formation member and at least one channel formation portion associated with the pattern formation member.

### BRIEF DESCRIPTION OF THE DRAWINGS

The accompanying drawings illustrate various embodiments of the present apparatus and method and are a part of the specification. The illustrated embodiments are merely examples of the present apparatus and method and do not limit the scope of the disclosure.

FIG. 1 illustrates a plan view of a joining material stencil according to one exemplary embodiment.

FIG. 2 is a flowchart illustrating a method of using a joining material stencil according to one exemplary embodiment.

FIGS. 3A and 3B illustrate a printed circuit board assembly according to one exemplary embodiment.

Throughout the drawings, identical reference numbers designate similar, but not necessarily identical, elements.

### DETAILED DESCRIPTION

The present specification describes a stencil for deposition of a heat yieldable joining material including at least one pattern formation member and at least one channel formation portion associated with the pattern formation member. The joining material stencil prevents melted solder from being sputtered or splashed out of a via and onto the rest of a PCB assembly.

As used in the present specification and in the appended claims, ‘stencil’ shall be broadly understood to mean any structure or assembly that facilitates the deposition of a material. Further, ‘vias’ shall be broadly understood to mean anything that facilitates a connection to electronic circuitry. In addition, as used herein, ‘out-gassing’ shall be broadly understood to mean anything that facilitates the evacuation or removal of fluid.

In the following description, for purposes of explanation, numerous specific details are set forth in order to provide a thorough understanding of the present method and apparatus. It will be apparent, however, to one skilled in the art that the present method and apparatus may be practiced without these specific details. Reference in the specification to “one embodiment” or “an embodiment” means that a particular feature, structure, or characteristic described in connection with the embodiment is included in at least one embodiment. The appearance of the phrase “in one embodiment” in various places in the specification are not necessarily all referring to the same embodiment.

### Exemplary Structure

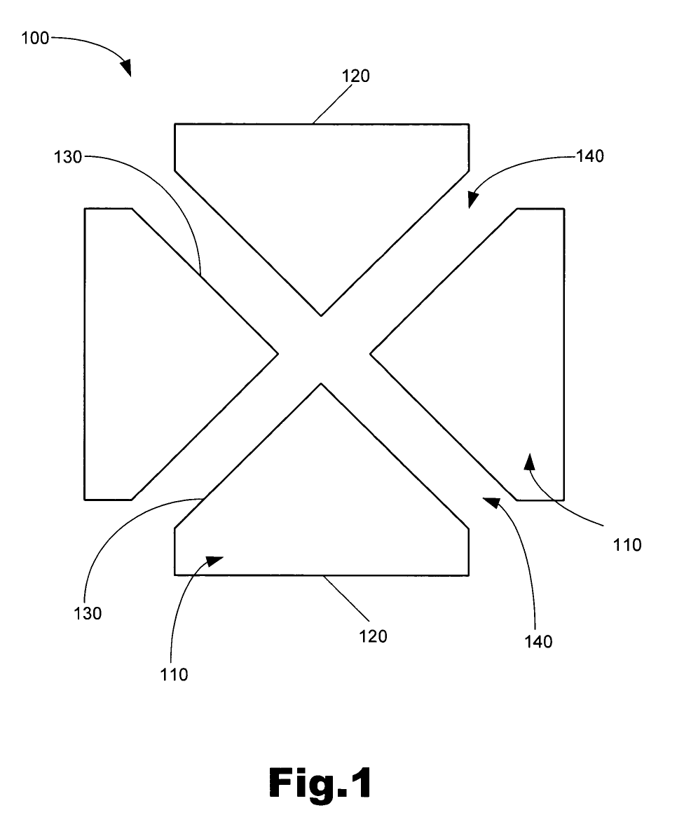

FIG. 1 illustrates a joining material stencil (100) according to one exemplary embodiment. As shown in FIG. 1 a joining material stencil (100) generally includes a plurality of joining material forming members (110). Each of the joining material forming members (110) includes a perimeter or outer boundary (120) and inner boundaries (130). Voids (140) are defined between the inner boundaries (130) of the joining material forming members (110). While the exemplary joining material stencil (100) illustrated in FIG. 1 shows the voids (140) in an “X” configuration, the present stencil and its associated method may be practiced with any number of void configurations and is in no way limited to the configuration illustrated in the figures.

The joining material stencil may be manufactured of any suitable material that facilitates the placement of a layer of solder paste on a PCB assembly. An example of a suitable material for the joining material stencil may include, but is in no way limited to, metals or plastics. Additionally, the joining material stencil may be manufactured by any appropriate manufacturing method currently known in the art including, but in no way limited to, injection molding, casting, milling, etc.

During the formation of a PCB, solder masks cover all exposed metal except the component pads and holes in order to prevent errant solder from inadvertently shorting (or electrically connecting) the printed traces. A solder mask is a material that does not bond with the solder or other joining material and is placed over circuitry to restrict solder wetting, thereby preventing the circuitry from being clogged by solder that would otherwise enter the circuitry by capillary action. The incorporation of solder masks allows metal surfaces other than the exposed pads and holes (i.e., the wires) to be safely located underneath the solder mask during processing.

Circuit components to be used on PCBs are manufactured with exposed metal pins (or leads) that are used to fasten them to the PCB both mechanically and electrically. The soldering process, which provides a strong mechanical bond and a very good electrical connection between circuit components and a PCB, is used to fasten these circuit components to the PCB. During soldering, component leads are inserted through the holes in the PCB and the component leads and the through-hole plating metal are heated to above the melting point of the solder (about 500 to 700 degrees Fahrenheit). Solder (a metallic compound) is then melted and allowed to flow in and around the component lead and through-hole.

If the entire component pad is covered with solder paste when the solder paste melts, the solder's surface tension will draw the melted solder into the vias and the component will have the tendency to rotate due to what is known as the Coriolis Effect. To prevent the solder paste from being drawin into the via, the via is covered with solder mask. However, if the via is covered with solder mask when the board is heated, gas inside the via expands and tends to behave like a small geyser. This can create solder splashes on the printed circuit board. This solder splash may short electronic circuitry, thereby rendering the PCB assembly defective.

The joining material stencil (100; FIG. 1) is used to form joining material or solder patterns on component pads of the PCB assembly. The stencil (100) is placed on the PCB assembly and joining material such as solder paste is applied over the stencil. The solder paste is smoothed and transfers though the joining material forming members (110). Once the solder paste has been smoothed, the stencil is removed forming a solder pattern on the PCB assembly. The joining material or solder is used to couple an electronic component to the PCB assembly. The present solder patterns are shaped to provide an out gassing channel that allows expanding air trapped inside circuitry and under a solder mask to escape during an initial heating stage of a joining operation. The joining operation and out gassing channel will be described in more detail below.

### Exemplary Implementation and Operation

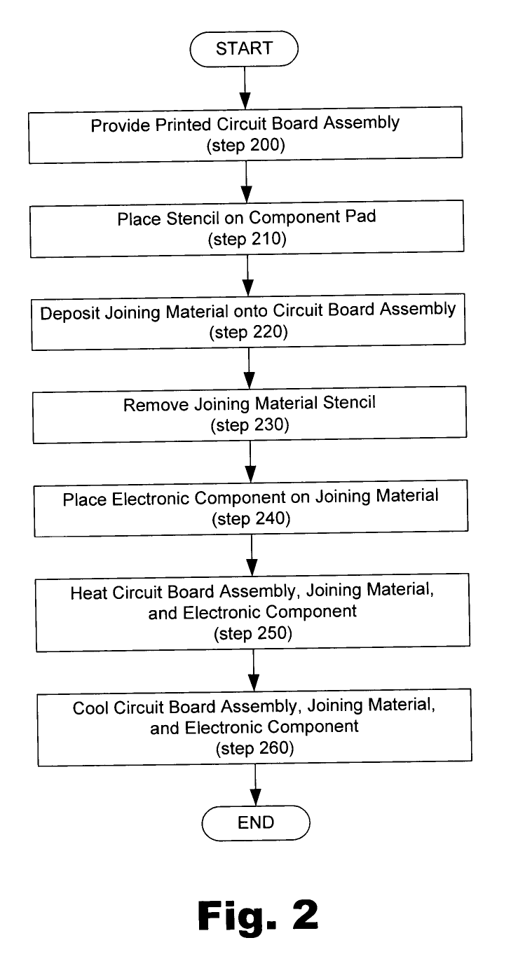

FIG. 2 is a flowchart illustrating a method of joining electronic components to a printed circuit board (PCB) assembly. As shown in FIG. 2, the process begins by providing a PCB assembly (step 200). Each PCB assembly provided may comprise several PCB layers. Each PCB layer provided includes a substrate of a suitable base material such as a thin sheet of fiberglass. Electronic circuitry that may include ground pads, signal pins, vias, etc. is then placed on the substrate. Some circuitry, such as ground pads, signal pins, etc, may be formed on the PCB layer by depositing a thin layer of metal and then selectively removing material as described above in order to leave the electronic circuitry. The circuitry and the substrate form an individual PCB layer. These layers may then be stacked to form a PCB assembly. Other circuitry, such as vias, may subsequently be fabricated by forming holes in the upper PCB layers to facilitate connection to electronic circuitry in internal layers of the PCB assembly. The vias may include conducting material, such as small gold ‘barrels’, to form the connection between different layers of the PCB assembly. In addition, the vias may be covered with a solder mask to prevent inadvertent shorting by errant solder. All of the described components are well known in the art and may be of the standard type commonly used.

Once the PCB assembly is provided (step 200), a joining material stencil (100; FIG. 1) is then placed on the component pad of the PCB assembly (step 210). The component pad may be a ground pad used in the production of a PCB. In addition, the joining material stencil (100; FIG. 1) includes a plurality of joining material forming members (110; FIG. 1), each member having a perimeter or outer boundary and inner boundaries. A layer of solder paste or other suitable joining material is then applied over the joining material stencil (step 220). Once applied, the joining material stencil (100; FIG. 1) allows the solder paste or other joining material to pass through the material forming members (110; FIG. 1) while preventing such a passage where the voids (140; FIG. 1) are located. The lack of solder paste or other joining material being transferred to the component pad of the PCB assembly forms a solder pattern with out-gassing channels defined between the solder patterns. Once the solder pattern is fomed, the stencil is removed (step 230) from the PCB assembly.

Once the solder pattern is formed and the stencil is removed, the electronic components are placed on the PCB assembly (step 240). Placement of the electronic components may be done manually or by a standard pick and place machine that places the electronic component on the solder paste. The PCB along with the component assembly is then heated (step 250). Heating of the PCB and the component assembly may be performed by any number of heating devices including, but in no way limited to, a convection oven. While heating the PCB and the component assembly (step 250) produces a number of results, the main purpose of the heating is to melt the solder paste. Once heated, the solder paste forms a liquid solder that has the tendency to flow. Concurrent with the heating of the solder paste, air trapped in the vias is heated and may expand. The voids (140; FIG. 1) established by the joining material stencil (100; FIG. 1) between the solder patterns serve as out-gassing channels to outgas expanding air contained in the vias while reducing or eliminating the sputtering of solder onto the rest of the PCB assembly. Air trapped in the vias will expand and escape the vias prior to the melting of the deposited solder. Once expanded, the air will be able to escape through the out-gassing channels. As the heating process continues, the solder patterns melt causing solder to flow around the solder masks covering the vias. The solder mask covers the vias and is made of a material that does not bond to the solder. Thus, the solder mask prevents the solder from being drawn into the vias. Accordingly, the use of this stencil pattern prevents melted solder from being sputtered or splashed onto the rest of the PCB assembly while allowing for maximum solder contact area between the component and the ground pad.

After the solder paste has melted, the PCB and component assembly is cooled (step 260). The cooling process solidifies the solder, thereby establishing a physical and an electrical connection between the PCB assembly and the components. The use of the above-mentioned stencil pattern may improve reliability of component joining operations due to the reduction of shorts or unintended electrical interconnections caused by clogged vias or sprayed solder and/or solder paste. This improvement may be accomplished with the use of standard PCB components and fabrication methods.

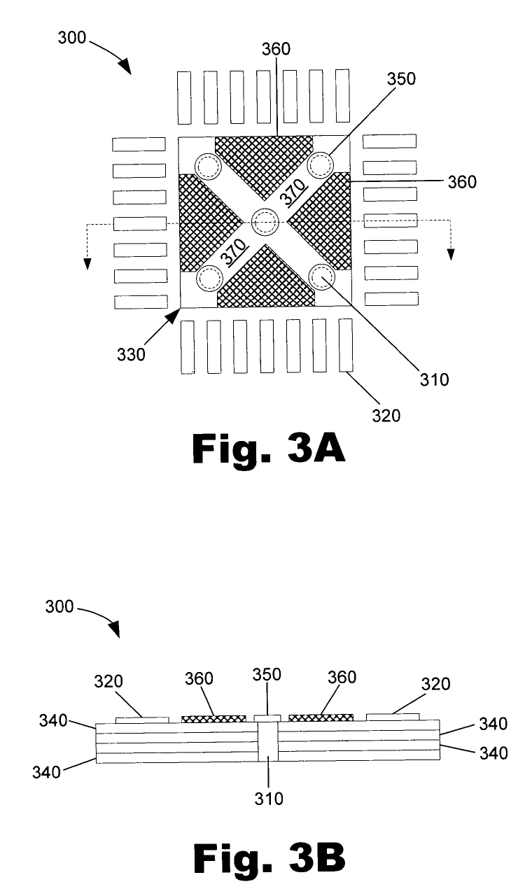

FIGS. 3A and B illustrate a printed circuit board (300) that includes vias (310) and electronic circuitry such as signal pins (320) and a ground pad (330). The vias (310) connect individual PCB layers (340) of the PCB (300) assembly. Further, the vias (310) are at least partially covered with solder mask (350) to restrict inadvertent solder wetting. Solder patterns (360) are formed on the ground pad (330) through the use of the joining material stencil (100; FIG. 1) during a deposition operation (step 220; FIG. 2). The voids (140; FIG. 1) between the inner boundaries (130; FIG. 1) of the joining material stencil (100; FIG. 1) form out-gassing channels (370) between the solder patterns (360) to provide channels configured to aid in the release of gas escaping from the vias (310) during an initial stage of a heating operation (step 240; FIG. 2). Covering the vias (310) with solder mask (350) reduces or eliminates the possibility of melted solder entering the vias through capillary action, and thus the rotation of an attached component due to the Coriolis Effect. Since the component does not rotate in the melted solder, the possibility of the melted solder shorting the signal pins (320) is significantly reduced or eliminated.

In conclusion, the joining material stencil may be configured to facilitate deposition of a joining material, such as solder, around any number of electrical components or circuitry. In the illustrated example, the joining material stencil facilitates deposition of solder around a group of vias. Those of skill in the art will understand that the joining material stencil may be configured to separate melted joining material from any number of electrical circuitry components, to facilitate the escape of trapped gas in any number or electrical components, and/or prevent rotation of electrical components due to Coriolis Effect. The preceding description has been presented only to illustrate and describe the present method and apparatus. It is not intended to be exhaustive or to limit the disclosure to any precise form disclosed. Many modifications and variations are possible in light of the above teaching. It is intended that the scope of the invention be defined by the following claims.

1. A stencil for forming heat yieldable joining material, comprising:
at least one pattern formation member; and
at least one channel formation portion associated with said pattern formation member.

2. The stencil of claim 1, wherein said channel is configured to form an out-gassing channel.

3. The stencil of claim 1, further comprising a plurality of pattern formation members.

4. The stencil of claim 3, wherein said channel is defined by a plurality of pattern formation members.

5. The stencil of claim 4, wherein a channel is defined between said pattern formation members.

6. The stencil of claim 5, wherein said plurality of pattern formation members comprises four pattern formation members and further comprising four channels defined between each of said pattern formation members.

7. The stencil of claim 6, wherein said channels form an ‘X’ pattern.

8. An electronic circuit board assembly, comprising:
a plurality of circuit boards
a via extending through at least one circuit board, wherein said via is coupled to at least one component pad; and
an electronic component coupled to said component pad by forming a joining material pattern on said component pad, said joining material pattern having at least one out-gassing channel.

9. The assembly of claim 8, wherein said coupling further comprises heating said electronic circuit board assembly above a melting point of said joining material and cooling said joining material to establish a physical and electrical couple.

10. The assembly of claim 8, further comprising a plurality of vias.

11. The assembly of claim 8, further comprising a joining material mask disposed on said via.

12. The assembly of claim 8, wherein said component pad comprises a ground pad.

13. A method of coupling circuit board assembly and electronic components, comprising:
providing a circuit board, wherein said circuit board includes at least one component pad and a via extending through at least one layer of said circuit board;
providing an electronic component;
disposing a joining material mask on said via;
forming a joining material pattern on said component pad, said joining material pattern including an out-gassing channel; and
heating said circuit board assembly and said electronic component.

14. The method of claim 13, further comprising cooling said circuit board assembly and said electronic component.

15. The method of claim 13, further comprising forming a plurality of joining material patterns on said component pad.

16. The method of claim 15, further comprising forming a plurality of joining material patterns on each of a plurality of said component pads.

17. The method of claim 13, wherein said joining material comprises solder.

18. The method of claim 13, wherein said component pad comprises a ground pad.
